(19) United States
(12) Patent Application Publication
(10) Pub. No.: US 2025/0037750 A1
(43) Pub. Date: Jan. 30, 2025

(54) MEMORY SELF-REFRESH POWER GATING

(71) Applicant: Advanced Micro Devices, Inc., Santa Clara, CA (US)

(72) Inventors: Indrani Paul, Austin, TX (US); Benjamin Tsien, Santa Clara, CA (US); James R. Magro, Austin, TX (US)

(73) Assignee: Advanced Micro Devices, Inc., Santa Clara, CA (US)

(21) Appl. No.: 18/783,900

(22) Filed: Jul. 25, 2024

Related U.S. Application Data
(60) Provisional application No. 63/515,694, filed on Jul. 26, 2023.

(51) Int. Cl. G11C 11/4074; G11C 5/14; G11C 11/406

(52) U.S. Cl. CPC G11C 11/4074; G11C 5/147; G11C 11/40615

(57) ABSTRACT

The disclosed systems and methods include a control circuit for entering a low power state of a memory by preserving a context of the memory's controller and power gating the memory's physical layer. The context can be saved to a non-volatile memory device or by keeping a retention supply voltage to a register of the memory controller. Various other methods, systems, and computer-readable media are also disclosed.

### CROSS REFERENCE TO RELATED APPLICATION

This application claims the benefit of U.S. Provisional Application No. 63/515,694, filed 26 Jul. 2023, the disclosure of which is incorporated, in its entirety, by this reference.

### BACKGROUND

A memory, such as a DRAM, can enter a low power state (e.g., a self-refresh in which data values are read and rewritten in order to refresh weakening charges). The low power state can include clock gating (e.g., powering off portions of a clock tree for delivering a clock signal) because the memory's physical layer (PHY) or logic components can be idle. Although the PHY is idle, power gating the PHY itself would require reconfiguring the memory's memory controller, which in some cases can require a system reboot. Thus, the low power or self-refresh state often includes only clock gating without power gating the PHY.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 is a block diagram of an exemplary system for memory self-refresh power gating.

FIG. 2 is a block diagram of an exemplary memory architecture.

FIG. 3 is a data flow diagram of context saving and restoring.

FIG. 4 is a flow diagram of an exemplary method for memory self-refresh power gating.

Throughout the drawings, identical reference characters and descriptions indicate similar, but not necessarily identical, elements. While the exemplary implementations described herein are susceptible to various modifications and alternative forms, specific implementations have been shown by way of example in the drawings and will be described in detail herein. However, the exemplary implementations described herein are not intended to be limited to the particular forms disclosed. Rather, the present disclosure covers all modifications, equivalents, and alternatives falling within the scope of the appended claims.

### DETAILED DESCRIPTION

The present disclosure is generally directed to a memory self-refresh power gating state. As will be explained in greater detail below, implementations of the present disclosure can enter a low power state for a memory by preserving a context of the memory's memory controller, and power gating a physical layer (e.g., logic components) of the memory, in addition to clock gating. In addition to power gating (e.g., as an example reference for removing power in the memory PHY), other examples of power removal that can be used include turning off a voltage supply for the PHY, and other appropriate power removal techniques. By preserving the context (e.g., by saving to a non-volatile memory device and/or providing a retention supply voltage to keep registers powered on), the systems and methods described herein allow the memory to power gate its logic components. As referred to herein, a non-volatile memory device can represent any type of non-volatility, such as a memory device that can preserve content when power is removed, and/or a memory device (such as SRAM) connected to a powered-on voltage rail (e.g., a retention supply that is different from a voltage supply to the PHY) to preserve content. The context preservation described herein can be low latency (e.g., meeting low power state entry/exit latency requirements) such that the low power state can include power gating. Thus, the systems and methods described herein allow the memory to enter a low power device that reduces power consumption beyond a power consumption reduction from clock gating.

In one implementation, a device for memory self-refresh power gating includes a control circuit configured to enter a low power state of a memory by preserving a context of a memory controller of the memory, and power gating a physical layer of the memory.

In some examples, the control circuit is configured to preserve the context of the memory controller by saving the context to a non-volatile memory device. In some examples, the control circuit is configured to preserve the context of the memory controller by supplying a retention supply voltage to one or more registers of the memory controller while power gating the physical layer. In some examples, the control circuit is configured to supply the retention supply voltage by enabling a bypass mode of a voltage regulator.

In some examples, the low power state corresponds to a self-refresh state of the memory. In some examples, the control circuit is further configured to exit the low power state of the memory by exit power gating the physical layer of the memory, and restoring the context of the memory controller.

In some examples, the control circuit is configured to restore the context of the memory controller by restoring the context from a non-volatile memory device. In some examples, exiting the power gating further comprises deactivating a retention supply voltage to one or more registers of the memory controller.

In one implementation, a system for memory self-refresh power gating includes a memory comprising a memory controller and a physical layer corresponding to a plurality of logic components, a non-volatile memory device, a processor, and a control circuit. The control circuit is configured to enter a low power state of the memory by preserving a context of a memory controller of the memory by saving the context to the non-volatile memory device, and power gating the physical layer of the memory.

In some examples, the control circuit is configured to preserve the context of the memory controller by supplying a retention supply voltage to one or more registers of the memory controller while power gating the physical layer. In some examples, the control circuit is configured to supply the retention supply voltage by enabling a bypass mode of a voltage regulator.

In some examples, the low power state corresponds to a self-refresh state of the memory. In some examples, the control circuit is further configured to exit the low power state of the memory by exit power gating the physical layer of the memory, and restoring the context of the memory controller.

In some examples, the control circuit is configured to restore the context of the memory controller by restoring the context from a non-volatile memory device. In some examples, exiting the power gating further comprises deactivating a retention supply voltage to one or more registers of the memory controller.

In one implementation, a method for memory self-refresh power gating includes (i) initiating, in response to a low power entry condition, entry to a low power state of a memory, (ii) saving a context of a memory controller of the memory to a non-volatile memory device, (iii) power gating a plurality of logic components of the memory, and (iv) retaining a retention supply voltage to power a register of the memory while power gating the plurality of logic components.

In some examples, retaining the retention supply voltage further comprises enabling a bypass mode of a voltage regulator. In some examples, the low power state corresponds to a self-refresh state of the memory.

In some examples, the method includes exiting the low power state of the memory. In some examples, exiting the low power state further comprises exiting power gating the plurality of logic components of the memory, restoring the context of the memory controller by restoring the context from the non-volatile memory device, and deactivating the retention supply voltage to the register.

Features from any of the implementations described herein can be used in combination with one another in accordance with the general principles described herein. These and other implementations, features, and advantages will be more fully understood upon reading the following detailed description in conjunction with the accompanying drawings and claims.

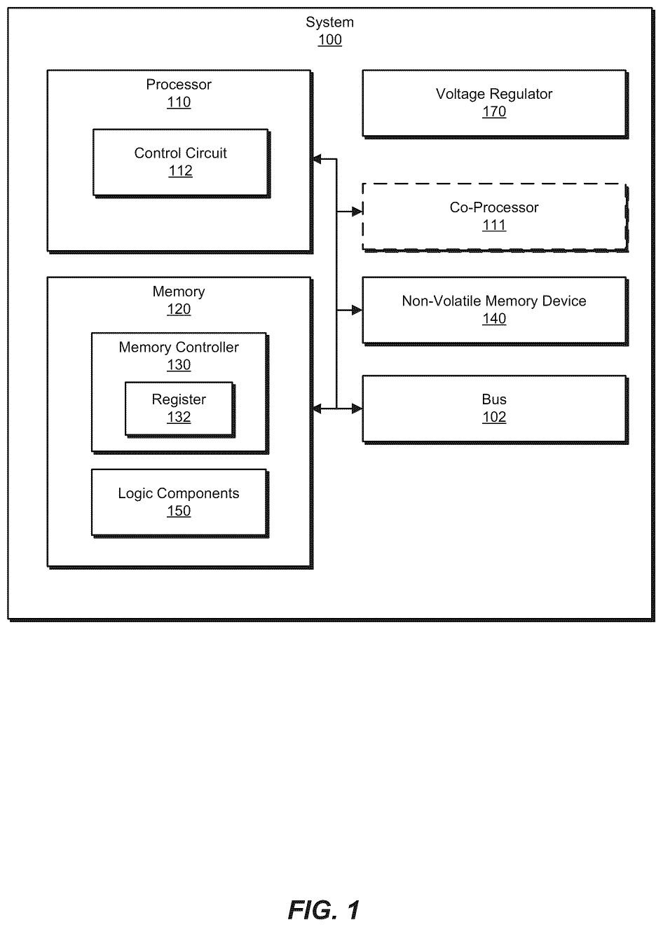

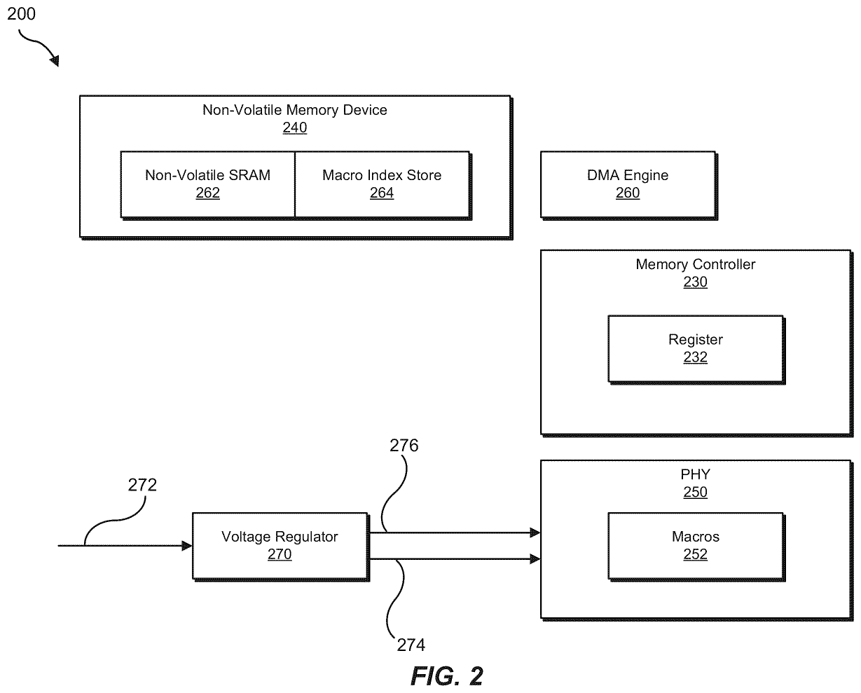

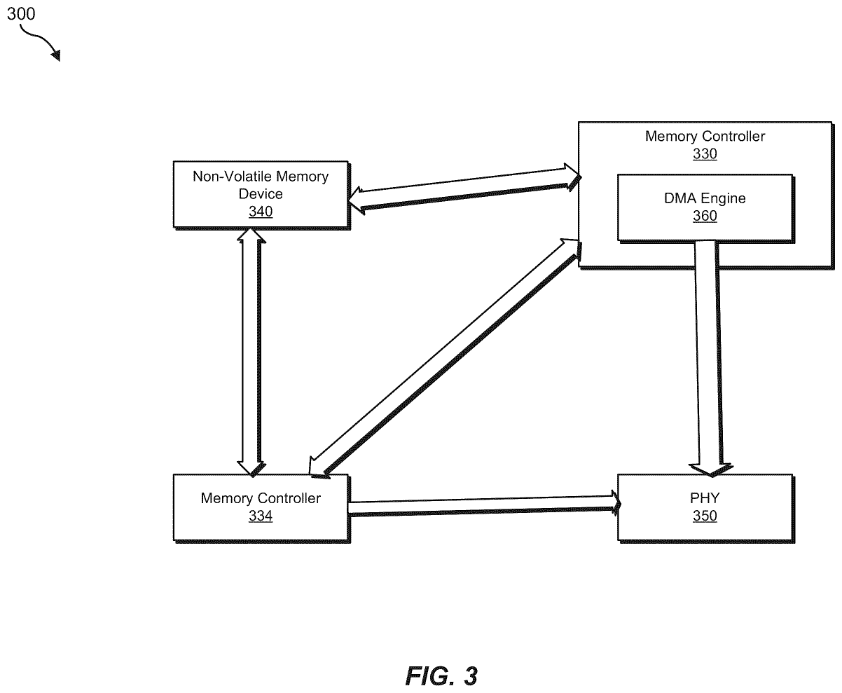

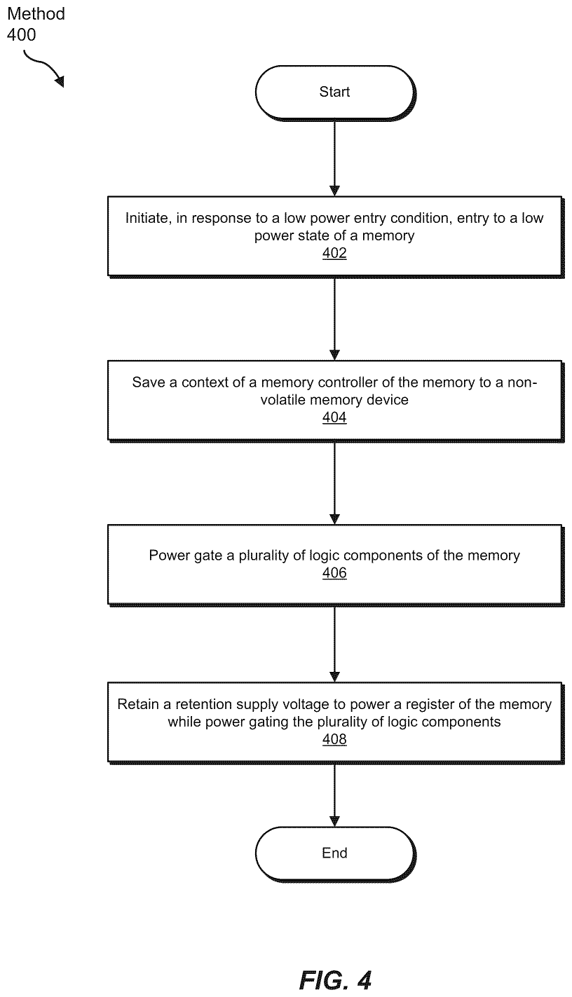

The following will provide, with reference to FIGS. 1-4, detailed descriptions of memory self-refresh power gating. Detailed descriptions of example systems will be provided in connection with FIGS. 1 and 2. Detailed descriptions of example context saving and restoring will be provided in connection with FIG. 3. Detailed descriptions of corresponding methods will also be provided in connection with FIG. 4.

FIG. 1 is a block diagram of an example system 100 for memory self-refresh power gating. System 100 corresponds to a computing device, such as a desktop computer, a laptop computer, a server, a tablet device, a mobile device, a smartphone, a wearable device, an augmented reality device, a virtual reality device, a network device, and/or an electronic device. As illustrated in FIG. 1, system 100 includes one or more memory devices, such as memory 120. Memory 120 generally represents any type or form of volatile or non-volatile storage device or medium capable of storing data and/or computer-readable instructions. Examples of memory 120 include, without limitation, Random Access Memory (RAM), Read Only Memory (ROM), flash memory, Hard Disk Drives (HDDs), Solid-State Drives (SSDs), optical disk drives, caches, variations, or combinations of one or more of the same, and/or any other suitable storage memory.

As illustrated in FIG. 1, memory 120 includes a memory controller 130 and logic components 150. Memory controller 130 corresponds to circuitry and/or instructions for controlling data traffic of memory 120. Memory controller 130 also includes a register 132 corresponding to one or more registers. Although illustrated as part of memory 120, in some implementations, memory controller 130 can be external to memory 120. Logic components 150 corresponds to a physical layer (PHY) of memory 120 and can include various circuits for implementing functions of memory 120, such as data storage circuits, etc.

As further illustrated in FIG. 1, example system 100 includes one or more physical processors, such as processor 110, which can correspond to one or more processors (e.g., a host processor along with a co-processor, which in some examples can be separate processors). Processor 110 generally represents any type or form of hardware-implemented processing unit capable of interpreting and/or executing computer-readable instructions. In some examples, processor 110 accesses and/or modifies data and/or instructions stored in memory 120. Examples of processor 110 include, without limitation, one or more instances of chiplets (e.g., smaller and in some examples more specialized processing units that can coordinate as a single chip), microprocessors, microcontrollers, Central Processing Units (CPUs), Field-Programmable Gate Arrays (FPGAs) that implement softcore processors, Application-Specific Integrated Circuits (ASICs), systems on chip (SoCs), digital signal processors (DSPs), Neural Network Engines (NNEs), accelerators, accelerated processing units (APUs), portions of one or more of the same, variations or combinations of one or more of the same (e.g., a host processor and a co-processor), and/or any other suitable physical processor(s). Further, in some examples, processor 110 can be a general-purpose processor that can be capable, without significant limitation, of various computing tasks, as opposed to a special purpose processor that can be limited in computing tasks (e.g., specially designed for particular computing tasks such as moving data, performing certain mathematical operations, etc.), although in other examples processor 110 can correspond to and/or incorporate one or more special purpose processors.

As also illustrated in FIG. 1, example system 100 can in some implementations optionally include one or more physical co-processors, such as co-processor 111, which in other implementations can be integrated with or otherwise represented by processor 110. Co-processor 111 generally represents any type or form of hardware-implemented processing unit capable of interpreting and/or executing computer-readable instructions, which in some examples works in conjunction and/or based on instructions from a host/main processor such as a CPU (e.g., processor 110). In some examples, co-processor 111 accesses and/or modifies data and/or instructions stored in memory 120. Examples of co-processor 111 include, without limitation, chiplets (e.g., smaller and in some examples more specialized processing units that can coordinate as a single chip), microprocessors, microcontrollers, graphics processing units (GPUs), Field-Programmable Gate Arrays (FPGAs) that implement softcore processors, Application-Specific Integrated Circuits (ASICs), systems on chip (SoCs), digital signal processors (DSPs), Neural Network Engines (NNEs), accelerators, accelerated processing units (APUs), portions of one or more of the same, variations or combinations of one or more of the same, and/or any other suitable physical processor.

FIG. 1 also includes a bus 102 that can correspond to any bus, circuitry, connections, and/or any other communicative pathways for sending communicative signals, based on one or more communication protocols, between components/devices (e.g., processor 110, memory 120, and/or co-processor 111, etc.). In some implementations, bus 102 can further connect, via wireless and/or wired connections, to other devices, such as peripheral devices external to or partially integrated with system 100.

As further illustrated in FIG. 1, processor 110 includes a control circuit 112. Control circuit 112 corresponds to circuitry and/or instructions for managing a low power state of memory 120 and in some examples can correspond to or otherwise interface with a power management circuit. FIG. 1 also shows system 100 including a voltage regulator 170 and a non-volatile memory device 140. Voltage regulator 170 corresponds to a power circuit (e.g., a low-dropout regulator or other voltage regulator circuit) for providing a supply voltage to at least memory 120, and can further be used for power gating memory 120 and/or components therein as will be described further below. Non-volatile memory device 140 corresponds to a memory device capable of retaining data, for instance a memory device that can remain powered on while voltage regulator 170 power gates memory 120, as will also be described further below.

FIG. 2 illustrates a system 200 corresponding to system 100 and/or memory 120. FIG. 2 includes a memory controller 230 corresponding to memory controller 130, a non-volatile memory device 240 corresponding to non-volatile memory device 140, a PHY 250 corresponding to logic components 150, and a voltage regulator 270 corresponding to voltage regulator 170.

FIG. 2 further illustrates a direct memory access (DMA) engine 260 corresponding to a circuit for accessing memory (e.g., independently from a processor), a non-volatile SRAM 262, and a PHY hard macro index store 264. SRAM 262 and PHY hard macro index store 264 can correspond to non-volatile memory device 240 and more specifically to a context (e.g., how macro blocks of memory are interconnected and correspond to indices and/or other memory configurations such as signal configurations) saved to non-volatile memory device 240. When system 200 enters a low power state such as a self-refresh state, a control circuit (e.g., control circuit 112 and/or other power management circuit) can save a context of memory controller 230 in non-volatile memory device 240, for example saving PHY hard macro index store 264 from a PHY hard macro index 252 as well as from other components of PHY 250 as needed. Saving the context allows the control circuit to power gate PHY 250 (and/or components therein) when entering the low power state and restoring the context upon exiting the low power state. For example, the control circuit can restore the context to a memory controller 230, PHY hard macro index 252, as well as other components of PHY 250 as needed.

The control circuit can power gate PHY 250 via voltage regulator 270, which can be a low-dropout regulator (LDO) receiving a memory voltage rail 272 (e.g., a power supply voltage for memory devices) from a system voltage regulator, and outputs a memory supply voltage 274 for powering PHY 250. Although an LDO is referred to herein, other examples of voltage sources can include external voltage regulators (e.g., PMICs), integrated voltage regulators (IVRs), etc. When power gating PHY 250, memory supply voltage 274 can be reduced to zero or near zero. However, certain values of the context can be stored in registers or other data storage devices that are not readily saved/restored with a context save/restore described above. For such cases, the control circuit can use a bypass mode of voltage regulator 270 to allow a retention supply voltage 276 (e.g., a power supply voltage less than memory supply voltage 274) to bypass the power gating and provide power to the aforementioned registers and/or data storage devices even with the rest of PHY 250 being power gated. The control circuit can deactivate retention supply voltage 276 (e.g., deactivate the bypass mode) when exiting power gating. Thus, even when power gating PHY 250, the context can be preserved.

In some implementations, an SRAM of PHY 250 (not illustrated) can retain power in all states, for example via retention supply voltage 276 during low power states and/or memory supply voltage 274 in other states. Other components of PHY 250 can be power gated during low power states. Further, in some implementations non-volatile memory device 240 can also retain power during low power states. As will be described further below, DMA engine 260 can restore the context by reading the context from non-volatile SRAM 262 and/or macro index store 264 and writing to memory controller 230 (e.g., register 232) and/or PHY 250 (e.g., PHY hard macro index 252 and/or other components such as an SRAM of PHY 250).

FIG. 3 illustrates a context save/restore process for a system 300 corresponding to system 100 and/or memory 120. FIG. 3 includes a memory controller 330 corresponding to memory controller 130, a non-volatile memory device 340 corresponding to non-volatile memory device 140, a PHY 350 corresponding to logic components 150, and a memory controller 334. In some implementations, memory controller 330 can correspond to a memory controller of a memory channel, and memory controller 334 can correspond to a microsequencer for multiple memory channels (e.g., interfacing with multiple iterations of memory controller 330), although in other implementations memory controller 330 and memory controller 334 can be organized into other hierarchies.

Based on a level of the low power state, various levels of the microcontrollers can be power gated. For example, in one power state, memory controller 330 and PHY 350 can be power gated. In this power state, a context (e.g., context of memory controller 330 and/or PHY 350) can be saved to non-volatile memory device 340. When exiting this power state, the context can be restored from non-volatile memory device 340 to memory controller 330. In some examples, the context can also be saved to and restored from memory controller 334. Memory controller 330 and/or memory controller 334 can further restore context to PHY 350 as needed (e.g., via DMA engine 360).

In another (lower) power state, memory controller 330, PHY 350, and memory controller 334 can be power gated. In this power state, the context (including a context of memory controller 334) can be saved to non-volatile memory device 340. When exiting this power state, the context can be restored to memory controller 334, which in turn can restore the context of memory controller 330. In other examples, non-volatile memory device 340 can directly restore memory controller 330. Memory controller 330 and/or memory controller 334 can further restore context to PHY 350 (e.g., via DMA engine 360). Further, in some implementations, when exiting the lower power state, a minimal portion of the total context (e.g., less than the total context) can be restored from non-volatile memory device 340 to memory controller 330 and/or memory controller 334 for regaining basic access to DRAM (e.g., a performance state with omission of performance optimized settings such as quality of service and/or other settings). After this partial context restore, memory controller 330 and/or memory controller 334 can restore the remaining context from memory while functioning in an operation state for a restricted set of clients. This partial context restore implementation can also reduce exit latency and minimize or otherwise mitigate capacity requirements of non-volatile memory device 340.

FIG. 4 is a flow diagram of an exemplary method 400 for memory self-refresh power gating. The steps shown in FIG. 4 can be performed by any suitable computer-executable code and/or computing system, including the system(s) illustrated in FIGS. 1, 2, and/or 3. In one example, each of the steps shown in FIG. 4 represent an algorithm whose structure includes and/or is represented by multiple sub-steps, examples of which will be provided in greater detail below.

As illustrated in FIG. 4, at step 402 one or more of the systems described herein initiate, in response to a low power entry condition, entry to a low power state of a memory. For example, control circuit 112 can initiate a low power state of memory 120 in response to a low power entry condition (e.g., logic components 150 being idle for a threshold period of time).

The systems described herein can perform step 402 in a variety of ways. In one example, low power state corresponds to a self-refresh state of the memory. In other examples, the low power state can correspond to any power state for reduced power consumption.

At step 404 one or more of the systems described herein save a context of a memory controller of the memory to a non-volatile memory device. For example, control circuit 112 can save a context of memory controller 130 to non-volatile memory device 140.

The systems described herein can perform step 404 in a variety of ways. In one example, saving the context can include saving the context from other devices to be power gated, such as saving a context for logic components 150. In some examples, saving the context can include saving, to non-volatile memory device 140, a context from register 132, such that register 132 and memory controller 130 can be power gated. In other examples, register 132 can bypass being power gated (as described herein) such that saving the context from register 132 can be omitted. In some implementations, memory 120 can include multiple different iterations of memory controller 130 (and register 132) such that some instances of memory controller 130 can be power gated and its corresponding register 132 having its context saved or remain powered via a retention supply voltage as described herein.

At step 406 one or more of the systems described herein power gate a plurality of logic components of the memory. For example, control circuit 112 can instruct voltage regulator 170 to power gate memory 120 (e.g., memory controller 130 and logic components 150). In some examples, voltage regulator 170 can power gate a memory supply voltage for memory 120. In some examples, based on the low power state, memory controller 130 can also be power gated with logic components 150.

At step 408 one or more of the systems described herein retain a retention supply voltage to power a register of the memory while power gating the plurality of logic components. For example, control circuit 112 can instruct voltage regulator 170 to retain (e.g., via a bypass mode) a retention supply voltage to power a register of memory (e.g., register 132 of memory controller 130) while power gating logic components 150.

The systems described herein can perform step 408 in a variety of ways. In one example, memory controller 130 can be power gated such that enabling the bypass mode allows supplying the retention supply voltage to register 132. In other examples, memory controller 130 can remain powered (e.g., not power gated with logic components 150) such that register 132 also remains powered.

In some examples, control circuit 112 can also exit the low power state of the memory by exit power gating logic components 150 of memory 120. Control circuit 112 can restore the context of memory controller 130 by restoring the context from non-volatile memory device 140 (e.g., restoring the saved context from non-volatile memory device 140 to memory controller 130 which can then restore the context to logic components 150). In addition, in exiting the power gating, control circuit 112 can deactivate (e.g., via voltage regulator 170) the retention supply voltage (e.g., ending the bypass mode) if the retention supply voltage was used.

As detailed above, memory devices often have a self-refresh (low power) state where the physical layer (PHY) can be completely clock gated, with no power gating of the PHY. The systems and methods described herein provide a low power state where PHY can power gate itself in addition to clock gating when entering memory self-refresh. The memory device can enter self-refresh when PHY is idle, such as in between traffic to DRAM for small periods of time.

The systems and methods described herein provide a low latency mechanism to enter memory self-refresh, which is used for various workloads as well as for display stutter traffic, which has real time QoS requirements. Entry and exit latency can be minimized for this low power state by using a combination of fast save-restore and DMA mechanisms, combined with SoC level power delivery that can quickly zero out the PHY voltage through a sideband handshake mechanism between the data fabric and voltage regulator (low dropout regulator). The systems and methods described herein provide a non-volatile memory (S5/VDDZ SRAM) used to save-restore UMC DMA engine to a state where it can restore the PHY.

The systems and methods described herein also provide a power delivery system to provide PHY retention voltage supply while turning off most (e.g., 90%) of the PHY logic power through a voltage regulator sideband req-ack handshake mechanism. The sideband handshake can be used to bypass the voltage regulator to provide just the retention voltage and zero out memory supply voltage to achieve power gating of the PHY. The systems and methods described herein further provide an encoding mechanism between data fabric and memory controller defined to instruct the PHY to enter this power gated state.

As detailed above, the computing devices and systems described and/or illustrated herein broadly represent any type or form of computing device or system capable of executing computer-readable instructions, such as those contained within the code/firmware/programs described herein. In their most basic configuration, these computing device(s) each include at least one memory device and at least one physical processor.

In some examples, the term “memory device” generally refers to any type or form of volatile or non-volatile storage device or medium capable of storing data and/or computer-readable instructions. In one example, a memory device stores, loads, and/or maintains one or more of the instructions and/or circuits described herein. Examples of memory devices include, without limitation, Random Access Memory (RAM), Read Only Memory (ROM), flash memory, Hard Disk Drives (HDDs), Solid-State Drives (SSDs), optical disk drives, caches, variations, or combinations of one or more of the same, or any other suitable storage memory.

In some examples, the term “physical processor” generally refers to any type or form of hardware-implemented processing unit capable of interpreting and/or executing computer-readable instructions. In one example, a physical processor accesses and/or modifies one or more instructions stored in the above-described memory device. Examples of physical processors include, without limitation, chiplets (e.g., smaller and in some examples more specialized processing units that can coordinate as a single chip), microprocessors, microcontrollers, Central Processing Units (CPUs), Field-Programmable Gate Arrays (FPGAs) that implement softcore processors, Application-Specific Integrated Circuits (ASICs), systems on chip (SoCs), digital signal processors (DSPs), Neural Network Engines (NNEs), accelerators, accelerated processing units (APUs), portions of one or more of the same, variations or combinations of one or more of the same (e.g., a host processor and a co-processor), and/or any other suitable physical processor.

In some examples, the term “physical processor” also refers to and/or includes a co-processor that generally refers to any type or form of hardware-implemented processing unit capable of interpreting and/or executing computer-readable instructions, which in some examples works in conjunction with and/or based on instructions from a host/main processor such as a CPU, and further in some examples accesses and/or modifies one or more instructions stored in the above-described memory device. Examples of co-processors include, without limitation, chiplets, microprocessors, microcontrollers, graphics processing units (GPUs), FPGAS that implement softcore processors, ASICs, SoCs, DSPs, NNEs, accelerators, portions of one or more of the same, variations or combinations of one or more of the same, and/or any other suitable physical processor.

Although described as separate elements/steps, the instructions described and/or illustrated herein can represent portions of a single program or application, including instructions implemented in code, firmware, one or more circuits, etc. In addition, in certain implementations one or more of these instructions can represent one or more software applications or programs that, when executed by a computing device, cause the computing device to perform one or more tasks. For example, one or more of the instructions described and/or illustrated herein represent instructions stored and configured to run on one or more of the computing devices or systems described and/or illustrated herein. In some implementations, one or more instructions can be implemented as a circuit or circuitry, including as part of a firmware, a ROM, one or more logic units, etc. One or more of these instructions can also represent or otherwise be implemented with all or portions of one or more special-purpose computers configured to perform one or more tasks.

In some implementations, the term “computer-readable medium” generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

The process parameters and sequence of the steps described and/or illustrated herein are given by way of example only and can be varied as desired. For example, while the steps illustrated and/or described herein are shown or discussed in a particular order, these steps do not necessarily need to be performed in the order illustrated or discussed. The various exemplary methods described and/or illustrated herein can also omit one or more of the steps described or illustrated herein or include additional steps in addition to those disclosed.

The preceding description has been provided to enable others skilled in the art to best utilize various aspects of the exemplary implementations disclosed herein. This exemplary description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A device comprising:
a control circuit configured to enter a low power state of a memory by:
preserving a context of a memory controller of the memory; and
power gating a physical layer of the memory.

2. The device of claim 1, wherein the control circuit is configured to preserve the context of the memory controller by saving at least a portion of the context to a non-volatile memory device.

3. The device of claim 1, wherein the control circuit is configured to preserve the context of the memory controller by supplying a retention supply voltage to one or more registers of the memory controller while power gating the physical layer.

4. The device of claim 3, wherein the control circuit is configured to supply the retention supply voltage by enabling a bypass mode of a voltage regulator.

5. The device of claim 1, wherein the low power state corresponds to a self-refresh state of the memory.

6. The device of claim 1, wherein the control circuit is further configured to exit the low power state of the memory by:
exit power gating the physical layer of the memory; and
restoring the context of the memory controller.

7. The device of claim 6, wherein the control circuit is configured to restore the context of the memory controller by restoring the context from a non-volatile memory device.

8. The device of claim 6, wherein exiting the power gating further comprises deactivating a retention supply voltage to one or more registers of the memory controller.

9. A system comprising:
a memory comprising a memory controller and a physical layer corresponding to a plurality of logic components;
a non-volatile memory device;
a processor; and
a control circuit configured to enter a low power state of the memory by:
preserving a context of a memory controller of the memory by saving at least a portion of the context to the non-volatile memory device; and
power gating the physical layer of the memory.

10. The system of claim 9, wherein the control circuit is configured to preserve the context of the memory controller by supplying a retention supply voltage to one or more registers of the memory controller while power gating the physical layer.

11. The system of claim 10, wherein the control circuit is configured to supply the retention supply voltage by enabling a bypass mode of a voltage regulator.

12. The system of claim 9, wherein the low power state corresponds to a self-refresh state of the memory.

13. The system of claim 9, wherein the control circuit is further configured to exit the low power state of the memory by:
exit power gating the physical layer of the memory; and
restoring the context of the memory controller.

14. The system of claim 13, wherein the control circuit is configured to restore the context of the memory controller by restoring the context from a non-volatile memory device.

15. The system of claim 13, wherein exiting the power gating further comprises deactivating a retention supply voltage to one or more registers of the memory controller.

16. A method comprising:
initiating, in response to a low power entry condition, entry to a low power state of a memory;
saving a context of a memory controller of the memory to a non-volatile memory device;
power gating a plurality of logic components of the memory; and
retaining a retention supply voltage to power a register of the memory while power gating the plurality of logic components.

17. The method of claim 16, wherein retaining the retention supply voltage further comprises enabling a bypass mode of a voltage regulator.

18. The method of claim 16, wherein the low power state corresponds to a self-refresh state of the memory.

19. The method of claim 16, further comprising exiting the low power state of the memory.

20. The method of claim 19, wherein exiting the low power state further comprises:
exiting power gating the plurality of logic components of the memory;
restoring the context of the memory controller by restoring the context from the non-volatile memory device; and
deactivating the retention supply voltage to the register.
